(19) United States
(12) Patent Application Publication
(10) Pub. No.: US 2026/0101502 A1
(43) Pub. Date: Apr. 9, 2026

(54) SEMICONDUCTOR DEVICE AND MANUFACTURING METHOD THEREOF

(71) Applicant: NANYA TECHNOLOGY CORPORATION, New Taipei City (TW)

(72) Inventor: Jung Tzu PENG, New Taipei City (TW)

(21) Appl. No.: 18/909,904

(22) Filed: Oct. 8, 2024

(51) Int. Cl. H10B 12/00

(52) U.S. Cl. CPC H10B 12/50

(57) ABSTRACT

A manufacturing method of a semiconductor device includes stacking a first hard mask layer on an active area layer; coating a photoresist on the first hard mask layer, in which the photoresist covers a first peripheral portion of the first hard mask layer; partially etching the first hard mask layer; side etching the photoresist to expose a second peripheral portion of the first hard mask layer; etching the first hard mask layer and the active area layer, in which after the etching, the active area layer has a ladder-shaped upper surface; and depositing a dielectric layer on the ladder-shaped upper surface.

### BACKGROUND

### Field of Invention

The present disclosure relates to a semiconductor device and a manufacturing method of a semiconductor device.

### Description of Related Art

The semiconductor integrated circuit (IC) industry has experienced exponential growth. Technological advances in IC materials and design have produced generations of ICs where each generation has smaller and more complex circuits than the previous generation. In the manufacturing of the peripheral circuit of memory cells, since the dual work function word line has different material than the bit line and the gate contact, it often takes two lithography processes (CA for word line, CS for bit line and gate contact) to form the conductive contact for the metal contact of the peripheral circuit, which causes a problem to overlay two masks on a same pattern.

### SUMMARY

One aspect of the present disclosure provides a manufacturing method of a semiconductor device.

According to one embodiment of the present disclosure, a manufacturing method of a semiconductor device includes stacking a first hard mask layer on an active area layer; coating a photoresist on the first hard mask layer, in which the photoresist covers a first peripheral portion of the first hard mask layer; partially etching the first hard mask layer; side etching the photoresist to expose a second peripheral portion of the first hard mask layer; etching the first hard mask layer and the active area layer, in which after the etching, the active area layer has a ladder-shaped upper surface; and depositing a dielectric layer on the ladder-shaped upper surface.

In some embodiment of the present disclosure, the manufacturing method of the semiconductor device further includes stacking a second hard mask layer on the first hard mask layer; and etching the second hard mask layer to form an opening.

In some embodiment of the present disclosure, the manufacturing method of the semiconductor device further includes forming a spacer on a sidewall of the opening of the second hard mask layer; and etching the second hard mask layer.

In some embodiment of the present disclosure, the manufacturing method of the semiconductor device further includes depositing a first conductive layer on the dielectric layer.

In some embodiment of the present disclosure, the manufacturing method of the semiconductor device further includes depositing a second conductive layer on the first conductive layer.

In some embodiment of the present disclosure, the manufacturing method of the semiconductor device further includes etching back the first conductive layer.

In some embodiment of the present disclosure, the manufacturing method of the semiconductor device further includes stacking a third hard mask layer on the active area layer.

Another aspect of the present disclosure provides a manufacturing method of a semiconductor device.

According to one embodiment of the present disclosure, a manufacturing method of a semiconductor device includes side etching a photoresist to expose a peripheral portion of a hard mask layer, in which the hard mask layer is located on an active area layer; etching the hard mask layer and the active area layer, in which after the etching, the active area layer has a ladder-shaped upper surface; depositing a first conductive layer on the ladder-shaped upper surface; etching back the first conductive layer; depositing a second conductive layer on the first conductive layer; and etching the second conductive layer to expose a peripheral portion of the first conductive layer, in which the peripheral portion of the first conductive layer overlaps with the peripheral portion of the hard mask layer on a vertical direction.

In some embodiment of the present disclosure, the manufacturing method of the semiconductor device further includes polishing the second conductive layer to expose a first dielectric layer.

In some embodiment of the present disclosure, the manufacturing method of the semiconductor device further includes depositing a second dielectric layer on the first conductive layer, the second conductive layer and the first dielectric layer; and forming a conductive contact in the second dielectric layer, in which the conductive contact contacts the peripheral portion of the first conductive layer.

In some embodiment of the present disclosure, the manufacturing method of the semiconductor device further includes depositing a third dielectric layer on the ladder-shaped upper surface.

In some embodiment of the present disclosure, the manufacturing method of the semiconductor device further includes stacking the hard mask layer on the active area layer.

In some embodiment of the present disclosure, the manufacturing method of the semiconductor device further includes coating the photoresist on the hard mask layer, wherein the photoresist covers a second peripheral portion of the hard mask layer.

In some embodiment of the present disclosure, the manufacturing method of the semiconductor device further includes partially etching the hard mask layer.

Another aspect of the present disclosure provides a semiconductor device.

According to one embodiment of the present disclosure, a semiconductor device includes a substrate, an active area layer, a first conductive layer and a second conductive layer. The active area layer is located on the substrate, in which the active area layer has a ladder-shaped upper surface. The first conductive layer is located on the active area layer. The second conductive layer is located on the first conductive layer, in which the second conductive layer doesn’t overlap with a peripheral portion of the first conductive layer.

In some embodiment of the present disclosure, the semiconductor device further includes a first dielectric layer. The first dielectric layer is located between the active area layer and the first conductive layer.

In some embodiment of the present disclosure, the semiconductor device further includes a second dielectric layer. The second dielectric layer is located on the active area layer, the first conductive layer and the second conductive layer.

In some embodiment of the present disclosure, the semiconductor device further includes a conductive contact. The conductive contact penetrates through the second dielectric layer and contacts the first conductive layer in the peripheral portion of the first conductive layer.

In some embodiment of the present disclosure, a work function of a material of the first conductive layer is different from a work function of a material of the second conductive layer.

In some embodiment of the present disclosure, the ladder-shaped upper surface includes a tilted surface.

In the aforementioned embodiments of the present disclosure, since the second conductive layer doesn’t overlap with the peripheral portion of the first conductive layer, the dual work function word line has the same material as the bit line on the peripheral portion, which means when forming the conductive contacts, the conductive contacts for word lines and the conductive contacts for bit lines can be form using one single mask(i.e. CS lithography process for word line, bit line and gate contact), which eliminates the problem of overlaying two masks on a same pattern.

### BRIEF DESCRIPTION OF THE DRAWINGS

FIG. 1 to FIG. 5 are cross-sectional views of intermediate steps of the manufacturing method of the semiconductor device according to one embodiment of the present disclosure.

FIG. 6 is a top view of the semiconductor device of FIG. 5.

FIG. 7 and FIG. 8 are cross-sectional views of intermediate steps of the manufacturing method of the semiconductor device according to one embodiment of the present disclosure.

FIG. 9 is a top view of the semiconductor device of FIG. 8.

FIG. 10 to FIG. 17 are cross-sectional views of intermediate steps of the manufacturing method of the semiconductor device according to one embodiment of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as "beneath," "below," "lower," "above," "upper" and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

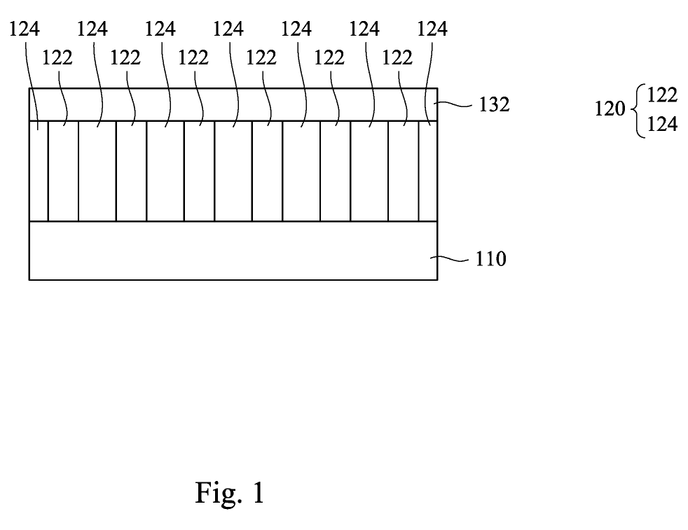

FIG. 1 to FIG. 5 are cross-sectional views of intermediate steps of the manufacturing method of the semiconductor device according to one embodiment of the present disclosure. Refer to FIG. 1, first, forming an active area layer 120 on a substrate 110. The active area layer 120 may include a plurality of active areas 122 and a shallow trench isolation 124. In a top view (not shown), the active areas 122 are surrounded by the shallow trench isolation 124. The material of the active areas 122 can includes silicon. The material of the shallow trench isolation 124 can include silicon oxide (SiO₂). Next, forming a first dielectric layer 132 on the active area layer 120. The material of the first dielectric layer 132 can include silicon nitride (SiN).

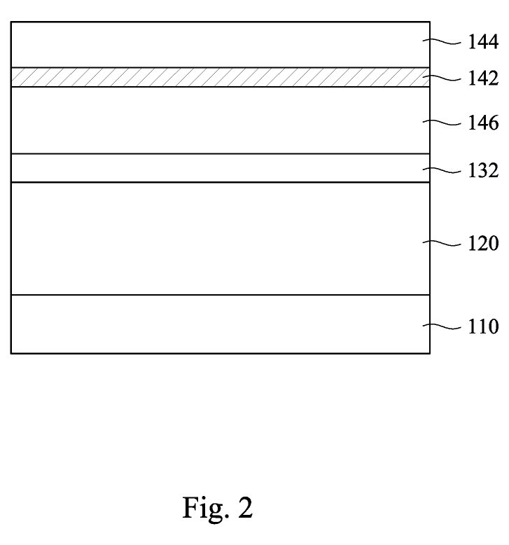

Refer to FIG. 2, thereafter, stacking a third hard mask layer 146, a first hard mask layer 142 and a second hard mask layer 144 in sequence on the first dielectric layer 132. That is, stack the third hard mask layer 146 on the first dielectric layer 132. Then, stack the first hard mask layer 142 on the third hard mask layer 146. Finally, stack the second hard mask layer 144 on the first hard mask layer 142. The first hard mask layer 142 can include dielectric antireflective coating hard mask. The second hard mask layer 144 can include a carbonized hard mask and a dielectric antireflective coating hard mask. The third hard mask layer 146 can include a carbonized hard mask, but the disclosure is not limited to this.

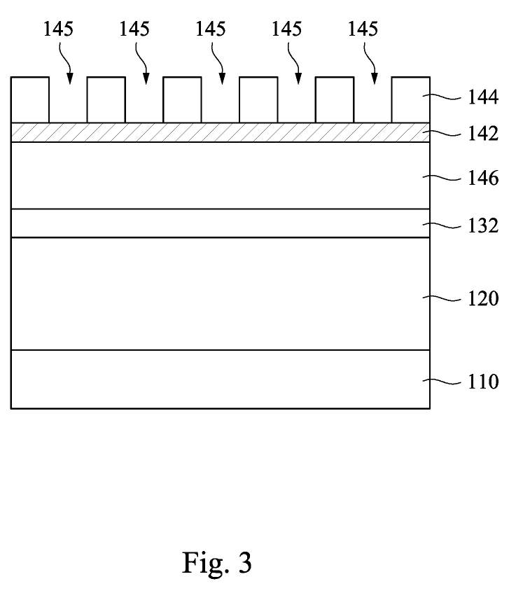

Refer to FIG. 3, thereafter, etching the second hard mask layer 144 to form a plurality of openings 145. The process can be done using dry etching, wet etching, a combination thereof, or the like. In FIG. 3, five openings 145 are shown. However, in real application, more or less openings 145 can be formed in this process.

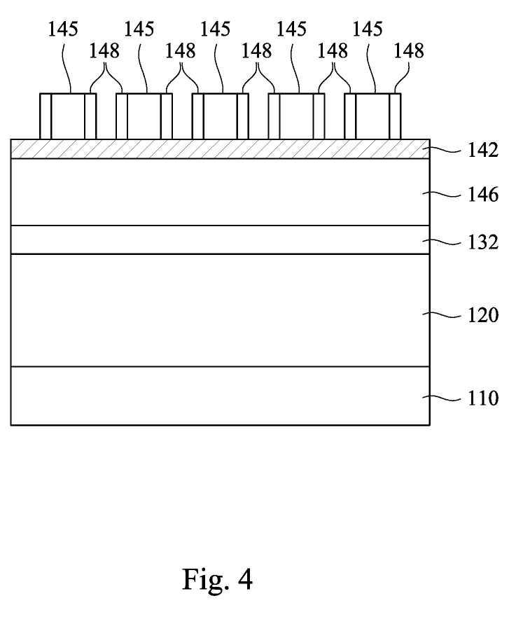

Refer to FIG. 4, thereafter, forming spacers 148 on the sidewalls of the openings 145 of the second hard mask layer 144. The spacers 148 can be formed using atomic layer deposition, chemical vapor deposition, a combination thereof, or the like. The material of the spacers 148 can include dielectric materials, such as silicon oxide, or other suitable materials.

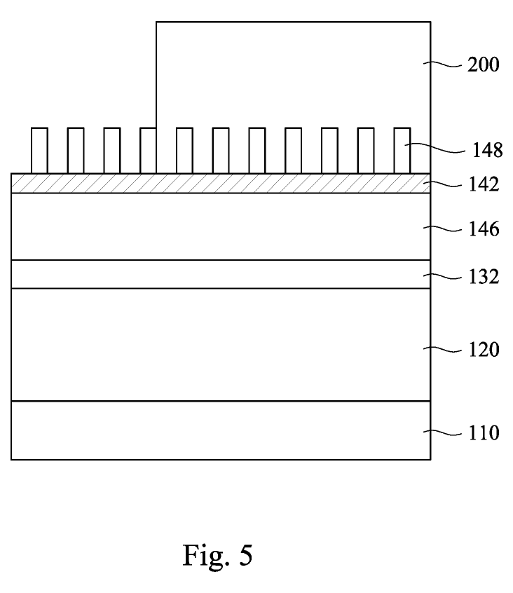

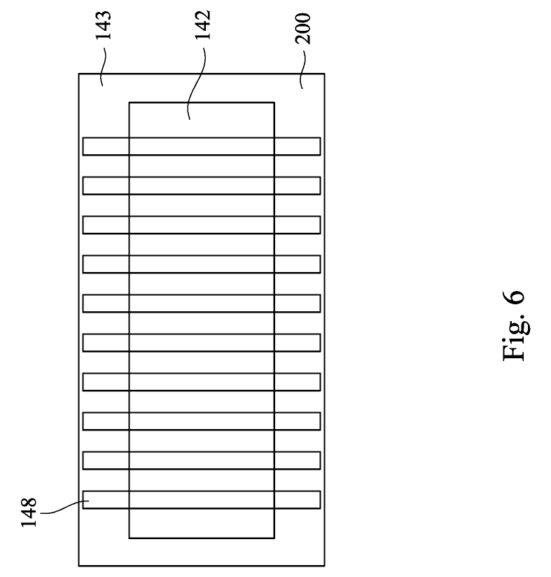

FIG. 6 is a top view of the semiconductor device of FIG. 5. Refer to FIG. 5 and FIG. 6, thereafter, etching the second hard mask layer 144. The process can further increase the density of the openings, which makes the critical dimension (CD) of the semiconductor device smaller. The etching of the second hard mask layer 144 can be dry etching, wet etching, a combination thereof, or the like. Thereafter, coating a photoresist 200 on the first hard mask layer 142, in which the photoresist 200 covers a first peripheral portion 143 of the first hard mask layer 142. The photoresist 200 only covers the outer part of the first hard mask layer 142 and the spacers 148. The thickness of the photoresist 200 is in a range of 0.5 μm to 1μm. The photoresist can include T6 resist, or other suitable photoresist.

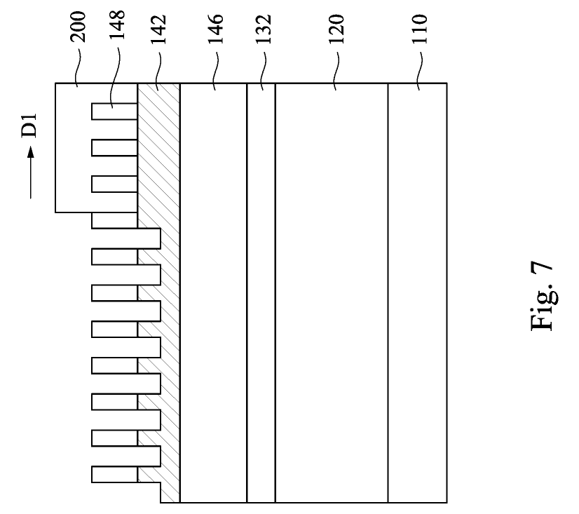

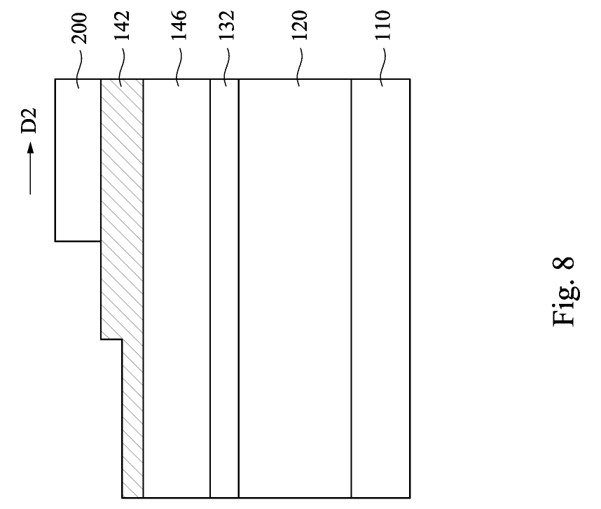

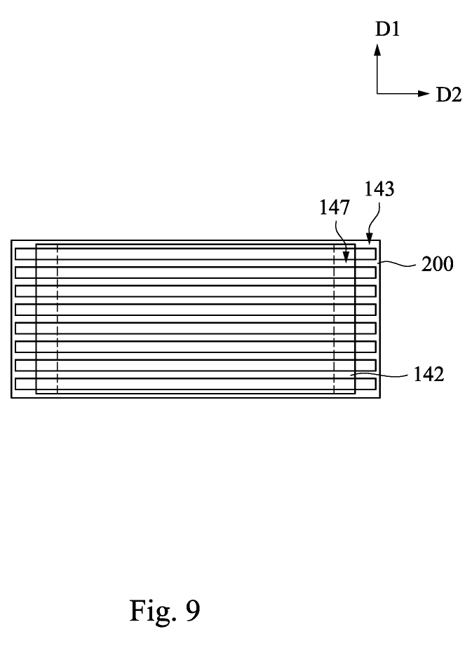

FIG. 7 and FIG. 8 are cross-sectional views of intermediate steps of the manufacturing method of the semiconductor device according to one embodiment of the present disclosure. Refer to FIG. 7, thereafter, partially etching the first hard mask layer 142. FIG. 1 to FIG. 7 are a cross-sectional views along a first direction D1 (see FIG. 9). Only half of the first hard mask layer 142 will be etched in this step, half of the first hard mask layer 142 will remain. The etching of the first hard mask layer 142 can be dry etching, wet etching, a combination thereof, or the like. The purpose of partially etching the first hard mask layer 142 is that at the next steps, a ladder-shaped surface is to be manufactured, such that it is necessary to keep half of the first hard mask layer 142 remain unetched for the next steps. During the process of the partially etching, the thickness of the photoresist 200 will decrease due to isotropic etching.

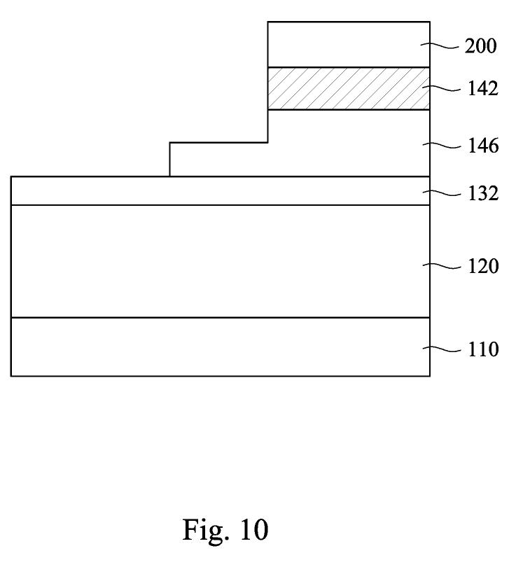

FIG. 9 is a top view of the semiconductor device of FIG. 8. Refer to FIG. 8 and FIG. 9, thereafter, side etching the photoresist 200 to expose a second peripheral portion 147 of the first hard mask layer 142. FIG. 8, FIG. 10 to FIG. 17 are cross-sectional views along a second direction D2. The second direction D2 is perpendicular to the first direction D1. In Fig, 8, the spacers 148 are omitted for clarity of description. The purpose of the side etching is to create a ladder-shaped upper surface at the first hard mask layer 142 for the etching thereafter.

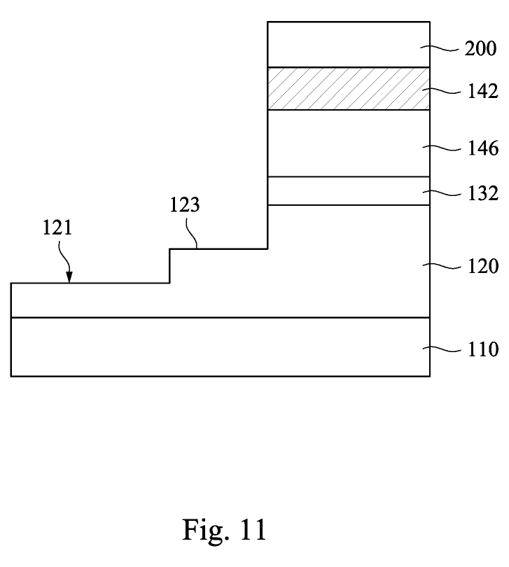

FIG. 10 to FIG. 17 are cross-sectional views of intermediate steps of the manufacturing method of the semiconductor device according to one embodiment of the present disclosure. Refer to FIG. 10 and FIG. 11, thereafter, etching the first hard mask layer 142, the third hard mask layer 146, the first dielectric layer 132 and the active area layer 120, in which after the etching, the active area layer 120 has a ladder-shaped upper surface 121. The ladder-shaped upper surface of the first hard mask layer 142 becomes the ladder-shaped upper surface 121 of the active area layer 120 in this step due to isotropic etching, which is the desired result of side etching the photoresist 200. The etching of the first hard mask layer 142, the third hard mask layer 146, the first dielectric layer 132 and the active area layer 120 can be dry etching, or the like. The peripheral portion 123 of the ladder-shaped upper surface 121 of the active area layer 120 overlaps with the second peripheral portion 147 of the first hard mask layer 142 on a vertical direction.

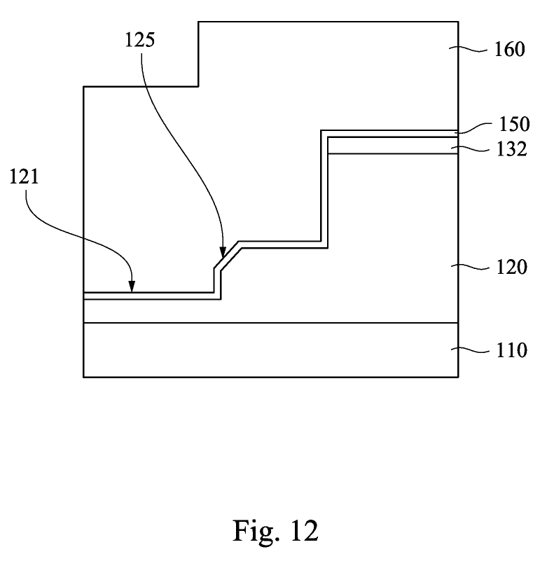

Refer to FIG. 12, thereafter, removing the first hard mask layer 142 and the third hard mask layer 146. Thereafter, depositing a second dielectric layer 150 on the ladder-shaped upper surface 121 of the active area layer 120 and the first dielectric layer 132. The material of the second dielectric layer can include silicon oxide, or other suitable dielectric materials. Thereafter, depositing a first conductive layer 160 on the second dielectric layer 150 (i.e. on the ladder-shaped upper surface 121). The material of the first conductive layer 160 can include conducing materials, such as tungsten, copper, silver, an alloy thereof, a combination thereof, or the like. The ladder-shaped upper surface 121 includes a tilted surface 125.

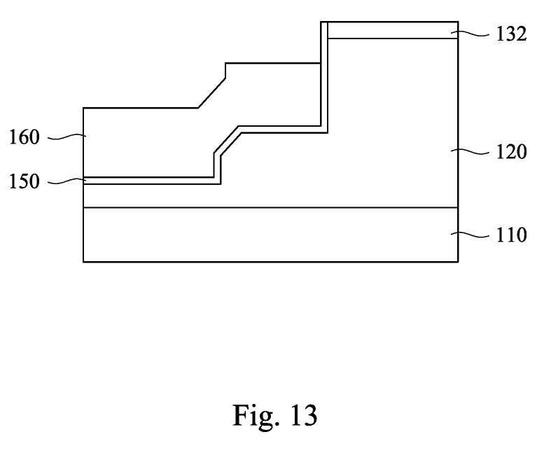

Refer to FIG. 13, thereafter, etching back the first conductive layer 160 and the second dielectric layer 150 to expose the first dielectric layer 132. The etching of the process can include dry etching of other suitable method. After the etching, only the portion that covers the first dielectric layer 132 of the second dielectric layer is etched.

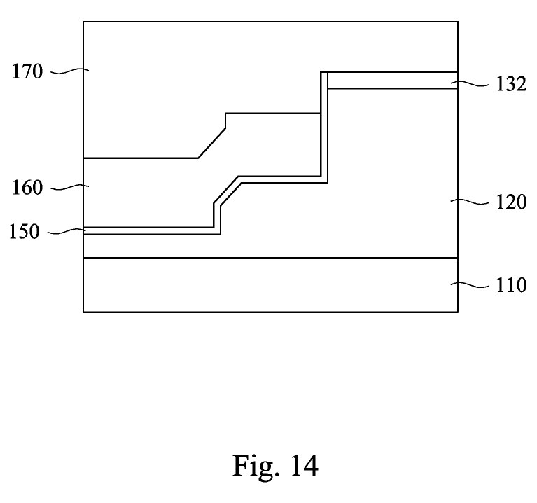

Refer to FIG. 14, thereafter, depositing a second conductive layer 170 on the first conductive layer 160. The material of the second conductive layer 170 can include conducing materials, such as poly silicon, tungsten, copper, silver, an alloy thereof, a combination thereof, or the like. The work function of the material of the first conductive layer 160 is different from the work function of the material of the second conductive layer 170. As an example, the first conductive layer 160 can be tungsten and the second conductive layer 170 can be poly silicon, but the disclosure is not limited to this.

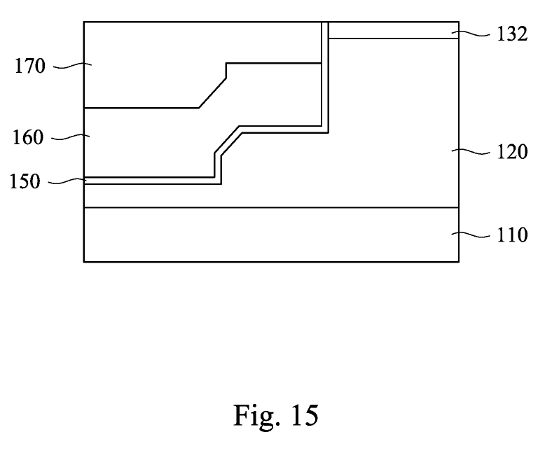

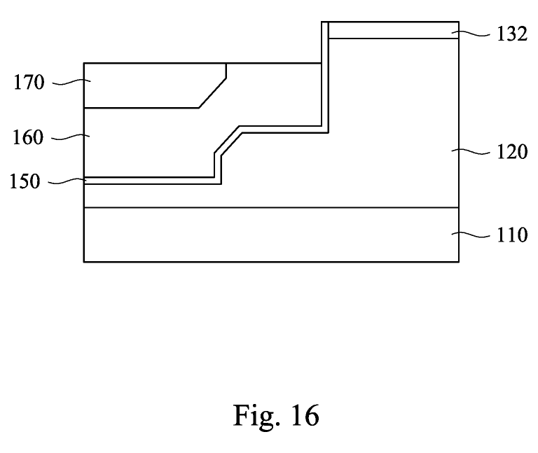

Refer to FIG. 15 and FIG. 16, thereafter, polishing the second conductive layer 170 to expose the first dielectric layer 132. The process can be done using chemical-mechanical polishing or other suitable methods. Thereafter, etching the second conductive layer 170 to expose a peripheral portion 161 of the first conductive layer 160, in which the peripheral portion 161 of the first conductive layer 160 overlaps with the second peripheral portion 147 of the first hard mask layer 142 on a vertical direction (see FIG. 8). The etching of the second conductive layer 170 can include dry etching of other suitable method.

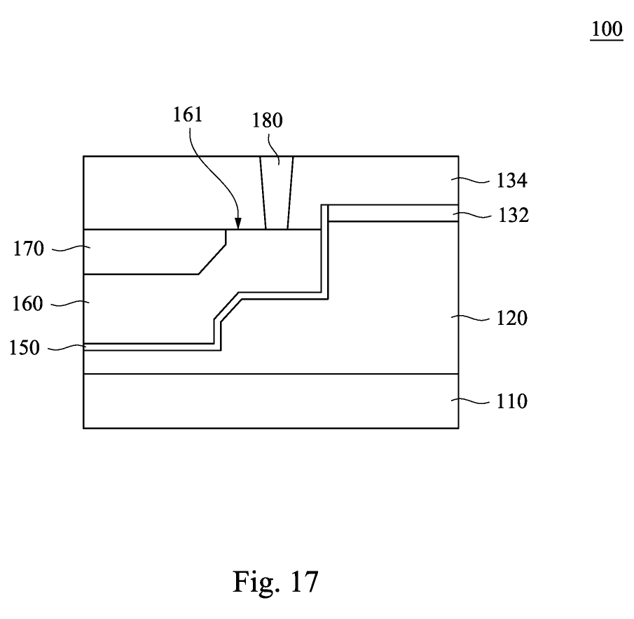

Refer to FIG. 17, thereafter, depositing a third dielectric layer 134 on the first conductive layer 160, the second conductive layer 170 and the first dielectric layer 132. The material of the third dielectric layer 134 can include silicon nitride or other suitable dielectric materials. Thereafter, forming a conductive contact 180 in the third dielectric layer 134, in which the conductive contact 180 contacts the peripheral portion 161 of the first conductive layer 160. After this step, the semiconductor device 100 is manufactured. The second conductive layer 170 doesn’t overlap the peripheral portion 161 of the first conductive layer 160, such that the conductive contact 180 will not contact the second conductive layer 170 while the conductive contact 180 penetrate the third dielectric layer 134 and contacts the first conductive layer 160.

In summary, since the second conductive layer 170 doesn’t overlap with the peripheral portion 161 of the first conductive layer 160, the dual work function word line has the same material as the bit line on the peripheral portion 161, which means when forming the conductive contacts 180, the conductive contacts 180 for word lines and the conductive contacts 180 for bit lines can be form using one single mask (i.e. CS lithography process for word line, bit line and gate contact), which eliminates the problem of overlaying two masks on a same pattern.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A manufacturing method of a semiconductor device, comprising:
stacking a first hard mask layer on an active area layer;
coating a photoresist on the first hard mask layer, wherein the photoresist covers a first peripheral portion of the first hard mask layer;
partially etching the first hard mask layer;
side etching the photoresist to expose a second peripheral portion of the first hard mask layer;
etching the first hard mask layer and the active area layer, wherein after the etching, the active area layer has a ladder-shaped upper surface; and
depositing a dielectric layer on the ladder-shaped upper surface.

2. The manufacturing method of the semiconductor device of claim 1, further comprising:
stacking a second hard mask layer on the first hard mask layer; and
etching the second hard mask layer to form an opening.

3. The manufacturing method of the semiconductor device of claim 2, further comprising:
forming a spacer on a sidewall of the opening of the second hard mask layer; and
etching the second hard mask layer.

4. The manufacturing method of the semiconductor device of claim 1, further comprising:
depositing a first conductive layer on the dielectric layer.

5. The manufacturing method of the semiconductor device of claim 4, further comprising:
depositing a second conductive layer on the first conductive layer.

6. The manufacturing method of the semiconductor device of claim 4, further comprising:
etching back the first conductive layer.

7. The manufacturing method of the semiconductor device of claim 1, further comprising:
stacking a third hard mask layer on the active area layer.

8. A manufacturing method of a semiconductor device, comprising:
side etching a photoresist to expose a peripheral portion of a hard mask layer, wherein the hard mask layer is located on an active area layer;
etching the hard mask layer and the active area layer, wherein after the etching, the active area layer has a ladder-shaped upper surface;
depositing a first conductive layer on the ladder-shaped upper surface;
etching back the first conductive layer;
depositing a second conductive layer on the first conductive layer; and
etching the second conductive layer to expose a peripheral portion of the first conductive layer, wherein the peripheral portion of the first conductive layer overlaps with the peripheral portion of the hard mask layer on a vertical direction.

9. The manufacturing method of the semiconductor device of claim 8, further comprising:
polishing the second conductive layer to expose a first dielectric layer.

10. The manufacturing method of the semiconductor device of claim 9, further comprising:
depositing a second dielectric layer on the first conductive layer, the second conductive layer and the first dielectric layer; and
forming a conductive contact in the second dielectric layer, wherein the conductive contact contacts the peripheral portion of the first conductive layer.

11. The manufacturing method of the semiconductor device of claim 8, further comprising:
depositing a third dielectric layer on the ladder-shaped upper surface.

12. The manufacturing method of the semiconductor device of claim 8, further comprising:
stacking the hard mask layer on the active area layer.

13. The manufacturing method of the semiconductor device of claim 8, further comprising:
coating the photoresist on the hard mask layer, wherein the photoresist covers a second peripheral portion of the hard mask layer.

14. The manufacturing method of the semiconductor device of claim 8, further comprising:
partially etching the hard mask layer.

15. A semiconductor device, comprising:
a substrate;
an active area layer located on the substrate, wherein the active area layer has a ladder-shaped upper surface;
a first conductive layer located on the active area layer; and
a second conductive layer located on the first conductive layer, wherein the second conductive layer doesn’t overlap with a peripheral portion of the first conductive layer.

16. The semiconductor device of claim 15, further comprising:
a first dielectric layer located between the active area layer and the first conductive layer.

17. The semiconductor device of claim 15, further comprising:
a second dielectric layer located on the active area layer, the first conductive layer and the second conductive layer.

18. The semiconductor device of claim 17, further comprising:
a conductive contact penetrating through the second dielectric layer and contacting the first conductive layer in the peripheral portion of the first conductive layer.

19. The semiconductor device of claim 15, wherein a work function of a material of the first conductive layer is different from a work function of a material of the second conductive layer.

20. The semiconductor device of claim 15, wherein the ladder-shaped upper surface comprises a tilted surface.
